(19) United States
(12) Patent Application Publication
(10) Pub. No.: US 2026/0041009 A1
(43) Pub. Date: Feb. 5, 2026

(54) SYSTEMS AND METHODS FOR THREE-DIMENSIONA STACKING OF SEMICONDUCTOR DIES IN A STAGGERED PATTERN

(71) Applicant: Eridu Corporation, Saratoga, CA (US)

(72) Inventors: Liang Wang, Newark, CA (US); Ting-Kuang Chiang, Saratoga, CA (US)

(73) Assignee: Eridu Corporation, Saratoga, CA (US)

(21) Appl. No.: 19/286,238

(22) Filed: Jul. 30, 2025

Related U.S. Application Data
(60) Provisional application No. 63/677,371, filed on Jul. 30, 2024.

(51) Int. Cl. H01L 25/00; H01L 21/56; H01L 23/00; H01L 23/31; H01L 23/48; H01L 25/065

(52) U.S. Cl. CPC H01L 25/50; H01L 21/568; H01L 23/3185; H01L 23/481; H01L 24/80; H01L 25/0655; H01L 2224/80895; H01L 2224/80896

(57) ABSTRACT

Consistent with aspects of the present disclosure, fabrication processes are provided for manufacturing 3-D stacked dies in a staggered pattern. Such processes yield device structures having adequate flatness and provide sufficient alignment for effective hybrid bonding in staggered 3-D die stacked package.

### BACKGROUND

### A. Technical Field

The present disclosure relates generally to systems and methods for semiconductor manufacturing. More particularly, the present disclosure relates to systems and methods for three-dimensional (3-D) integration technology, such as for stacking semiconductor dies with high 3-D interconnect density.

### B. Background

The advancement of high-performance computing and telecommunications technologies has driven the demand for innovative semiconductor architectures. Petabit optical switches, which offer unprecedented data transfer rates and processing capabilities, and similar high-speed devices would greatly benefit from a multi-die design that involves hybrid-bonding. Hybrid-bonding incorporates both electrical (e.g., copper-to-copper) and mechanical (e.g., oxide or nitride) connections, enhancing component density and electrical performance by bonding one layer of semiconductor known-good-dies (KGDs) to another.

FIG. 1A through FIG. 1C depict a traditional hybrid bonding process that combines a dielectric (silicon oxide or nitride) bond with embedded metal (e.g., copper) to form interconnections. Initially, a direct bond between the dielectric material (oxide or nitride) is formed at room temperature, as depicted in FIG. 1A. Subsequent heating closes the dishing gap due to the coefficient of thermal expansion (CTE) of metal compared to silicon oxide or nitride. Finally, further heating compresses the metal without external pressure such as to achieve a permanent bond in the integrated product, as depicted in FIG. 1C.

Some semiconductor design and packaging methods bond a top die to two or more adjacent bottom dies, or vice versa, where a bottom die is bonded to two or more adjacent top dies. In a staggered 3-D die stacking, both the top and bottom dies are bonded to multiple adjacent dies in the other layer. The electrical connections between top and bottom dies occur at a fine pitch, currently as low as about 20 μm, using solder-based interconnections. For higher interconnect density and improved signal transmission speeds, a single-digit micron scale pitch based on hybrid bonding interconnections is desirable. However, variations in die thickness inhibit successful hybrid bonding when using existing methods, as hybrid bonding to KGDs requires nanometer-scale flatness at the bonding interface to ensure precise control of bonding surfaces in contact without void. Even minor variations in die thickness can lead to poor contact and bonding quality, compromising the performance and reliability of the final product.

Existing Fan-Out Wafer-Level Packaging (FOWLP) approaches attempt to address coplanarity challenges between dies by using a molding technique to achieve the desired flatness. FOWLP encapsulates the dies in a molding material, which is then planarized to create a flat surface for subsequent processing. However, such approaches suffer from die shift, a significant drawback that occurs due to uncontrolled mold flow during the encapsulation process, causing the dies to move away from their intended positions. These shifts can lead to misalignments of dies with respect of the redistribution layer (RDL) patterns needed to establish proper electrical connections between dies.

Adaptive correction methods that counter die shift by dynamically adjusting the RDL patterns to follow the shifted dies have proven insufficient for achieving the precise alignment required for hybrid bonding and staggered 3-D die stacking. The inherent variability in the mold flow and the subsequent die positions create inconsistencies that cannot be fully compensated, resulting in unreliable bonding interfaces and degraded device performance.

Accordingly, what is needed are systems and methods that overcome existing process challenges and provide improved solutions for achieving the required flatness and precise alignment for effective hybrid bonding in staggered 3-D die stacking.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments. Items in the figures are not to scale.

FIG. 1A through FIG. 1C depict a traditional hybrid bonding process.

FIG. 2A through FIG. 2I illustrate a process for 3-D stacking dies in a staggered pattern according to various embodiments of the present disclosure.

FIG. 3A through FIG. 3I illustrate another process for 3-D stacking dies in a staggered pattern according to various embodiments of the present disclosure.

FIG. 4A through FIG. 4I illustrate yet another process for 3-D stacking dies in a staggered pattern according to various embodiments of the present disclosure.

FIG. 5 through FIG. 7 illustrate alternative embodiments according to various embodiments of the present disclosure.

FIGS. 8A and 8B show examples of vias consistent with an aspect of the present disclosure;

FIG. 9 illustrates an exemplary three-layer stack according to various embodiments of the present disclosure.

FIG. 10A through FIG. 10D are top views of exemplary multi-die interconnection arrangements according to various embodiments of the present disclosure.

FIG. 11 through FIG. 13 are flowcharts of illustrative processes for 3-D stacking dies in a staggered pattern according to various embodiments of the present disclosure.

### DETAILED DESCRIPTION OF EMBODIMENTS

In the following description, for purposes of explanation, specific details are set forth in order to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, or modules, shown in diagrams are illustrative of exemplary embodiments of the disclosure and are meant to avoid obscuring the disclosure. It shall be understood that throughout this discussion components may be described as separate functional units, which may comprise sub-units, but those skilled in the art will recognize that various components, or portions thereof, may be divided into separate components or may be integrated, including, for example, being in a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” “communicatively coupled,” “interfacing,” “interface,” or any of their derivatives shall be understood to include direct connections, indirect connections through one or more intermediary devices, and wireless connections. It shall also be noted that any communication, such as a signal, response, reply, acknowledgment, message, query, etc., may comprise one or more exchanges of information.

Reference in the specification to “one or more embodiments,” “preferred embodiment,” “an embodiment,” “embodiments,” or the like means that a particular feature, structure, characteristic, or function described in connection with the embodiment is included in at least one embodiment of the disclosure and may be in more than one embodiment. Also, the appearances of the above-noted phrases in various places in the specification do not necessarily all refer to the same embodiment or embodiments.

The use of certain terms in various places in the specification is for illustration and should not be construed as limiting. The terms “include,” “including,” “comprise,” “comprising,” and any of their variants shall be understood to be open terms, and any examples or lists of items are provided by way of illustration and shall not be used to limit the scope of this disclosure.

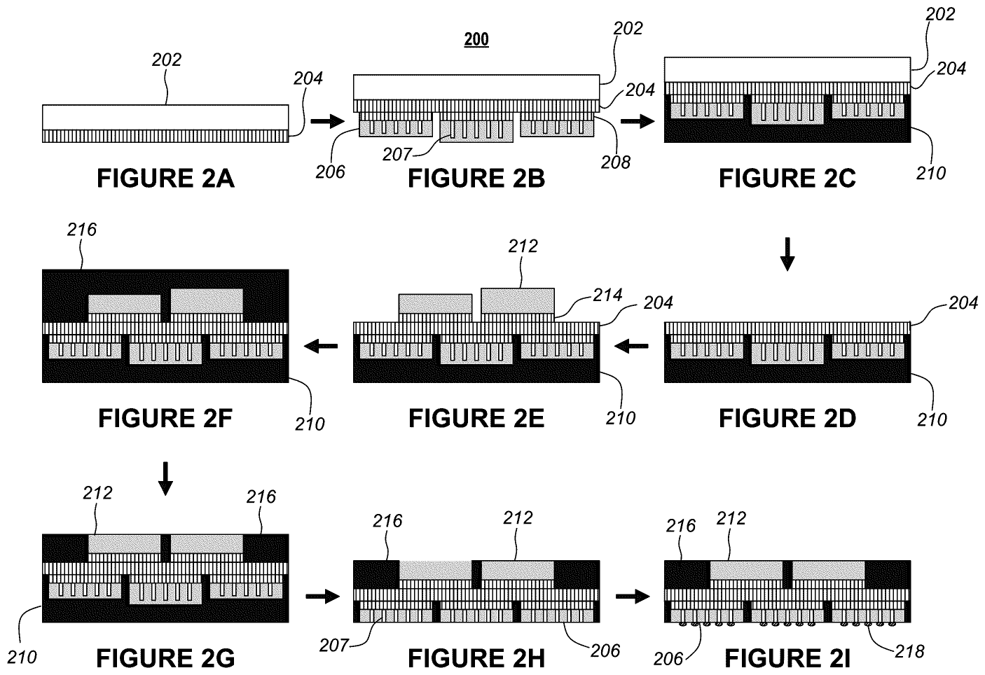

The following detailed description of example implementations refers to the accompanying drawings. The same reference numbers in different drawings may identify the same or similar elements. Moreover, the same or similar features in FIGS. 2A-2I, 3A-3I, 4A-4I, 5-7, and 9, may have the same shading or patterning. Accordingly, a description of such features in one of these figures may be omitted in other figures if such features are the same or similar throughout the drawings.

FIG. 2A through FIG. 2I illustrate a process for 3-D stacking dies in a staggered pattern according to various embodiments of the present disclosure. As depicted, process 200 starts with arranging an array of hybrid bond pads (hereinafter “intermediate array”) 204 in a hybrid bond pattern on temporary carrier 202. In embodiments, temporary carrier 202 is used to manufacture a product that comprises bottom KGDs 206 and top KGDs 212, depicted in FIG. 2I.

Bottom KGDs 206 comprise, in addition to Through-Silicon Vias (TSVs) 207, hybrid bond pads 208, which in the manufactured product are encapsulated with one or more encapsulating materials 210 (e.g., an epoxy-based molding compound, silicon oxide, or any combination thereof) to create a wafer-like structure that can be processed similarly to a traditional semiconductor wafer. Similarly, top KGDs 212 comprise hybrid bond pad 214 and are encapsulated with encapsulating material 216.

As depicted in FIG. 2A, intermediate array 204 is disposed on temporary carrier 202, which, may be fabricated from materials such as glass, silicon, polymers, and the like, and, in embodiments, be pre-patterned with intermediate array 204. The hybrid bonding pads of intermediate array 204 may comprise electrical pads made from electrically conductive material (e.g., copper) that serve as points of electrical contact and a mechanical medium made from dielectric material (e.g., silicon oxide or silicon nitride) that are interspersed among the electrical pads to serve as points of mechanical contact. It is understood that the hybrid nature of such designs is not limited to any particular material or material combination as hybrid bonding may be implemented, for example, with organic polymer-based materials. It is further understood that pads may comprise alignment marks, which may be strategically placed at the periphery or within pad patterns to ensure that KGDs (e.g., 206) with hybrid bond pad patterns that are configured to match the bonding patterns of the hybrid bond pads of intermediate array 204 correctly align during the alignment step of the bonding process that hybrid-bonds bottom KGDs 206 to temporary carrier 202. It is understood that intermediate array 204 may comprise routing patterns and/or additional electrical connections, such as metal traces through encapsulation vias that are embedded in encapsulating material 210 and form electrical connections (not shown).

As depicted in FIG. 2B, the bonding pattern of intermediate array 204 matches that of KGDs 206, which are hybrid-bonded to the bottom side of temporary carrier 202. This hybrid bonding creates a strong and reliable interface between KGDs 206 intermediate array 204. As a result, any die shift in bottom KGDs 206 will be negligible, and the positions of bottom KGDs 206 will be correctly locked in place. It is understood that TSVs 207 represent any vertical interconnections through KGDs 206 used for signal transmission, power supply, control command, and the like.

As depicted in FIG. 2C, the wafer structure may be reconstituted, e.g., with encapsulating material 210. In embodiments, a thick (e.g., 30 μm) oxide may deposited at low temperatures onto bottom or top KGDs to form encapsulation 210 or 216 instead, by using any deposition method known in the art. Compared to common molding materials, oxide is known to be less prone to limitations posed by temperature-induced shrinkage caused by the large CTE of common molding materials, which may impact the yield and reliability of the hybrid bonding process. At this point, the wafer structure comprises individual KGDs 206 embedded in encapsulating material 210, which fills the spaces between KGDs 206.

As depicted in FIG. 2D, temporary carrier 202 may be removed by using a carrier debond, backgrinding, or etching process followed by any planarization process known in the art, such as chemical mechanical polishing (CMP) or electrochemical planarization (ECP), thereby exposing the hybrid bonds of intermediate array 204.

As depicted in FIG. 2E, top KGDs 212 are then hybrid-bonded to the bond pads of intermediate array 204 to achieve hybrid bonding on both sides of intermediate array 204. Once the positions of both top KGDs 212 and bottom KGDs 206 are locked in place, top KGDs 212 may be encapsulated with one or more encapsulating materials 210, as depicted in FIG. 2F. This may be achieved, for example, by using a gap-fill process, an overmolding process, or by covering top KGDs 212 with thick oxide at low temperatures, e.g., to prevent inter-metal melting and diffusion of implanted dopants during high-temperature processing steps.

As depicted in FIG. 2G, the tops of top KGDs 212 may be flattened, e.g., by a planarization process that creates a flat and uniform surface. Although not expressly discussed in detail herein, various embodiments may comprise any number of additional steps to achieve the objectives of the present disclosure, such as surface preparation steps. As an example, a cleaning process that removes contaminants, which otherwise may interfere with the bonding process, may be applied following a planarization step.

As depicted in FIG. 2H, the backsides of bottom KGDs 206 may be thinned and flattened to reveal TSVs 207.

Finally, as depicted in FIG. 2I, one or more Under Bump Metallization (UBM) layers may be deposited on the contact pads of KGDs 206, onto which then solder bumps may formed, for example, by using any copper pillar solder capped micro bump plating process known in the art.

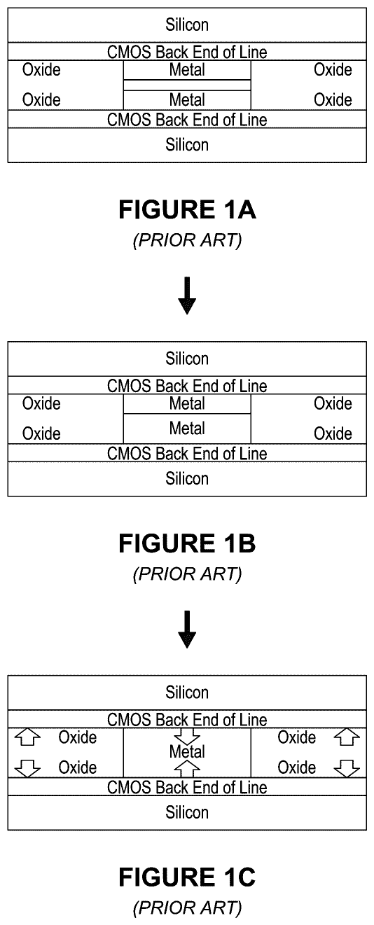

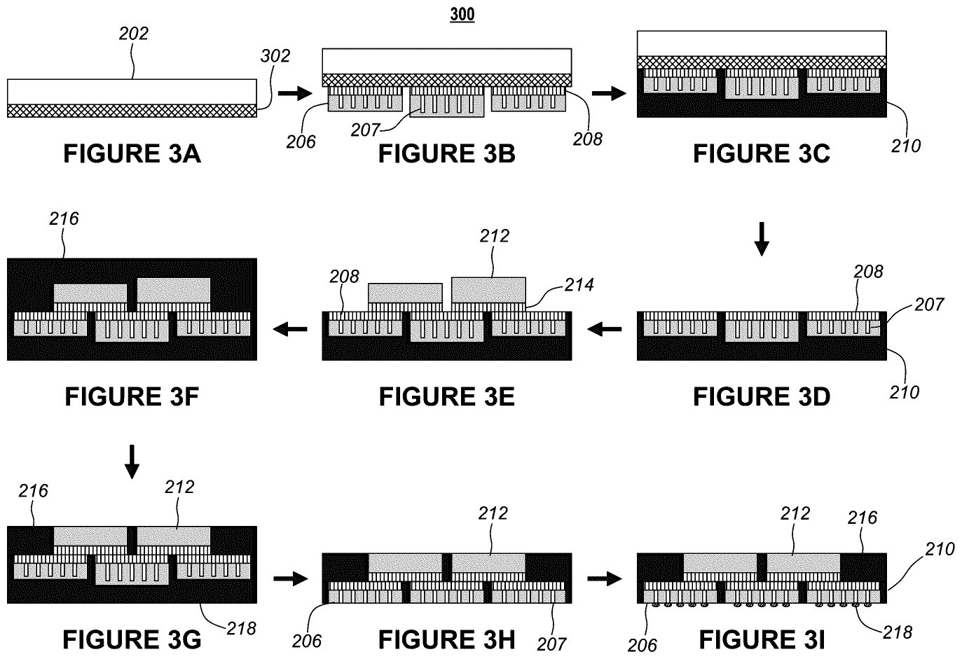

FIG. 3A through FIG. 3I illustrate another process for 3-D stacking dies in a staggered pattern according to various embodiments of the present disclosure. For clarity, components similar to those shown in FIG. 3A are labeled in the same manner. For purposes of brevity, a description or their function is not repeated here. FIG. 3A depicts a temporary carrier 202 onto which dielectric layer 302 (e.g., silicon oxide or silicon nitride) is deposited. In embodiments, temporary carrier 202 comprises alignment marks (not shown) that ensure the correct positioning of the KGDs. In these embodiments, instead of utilizing a hybrid bond pattern as previously described with reference to FIG. 2A to FIG. 1, bottom KGDs 206 are bonded onto dielectric layer 302, e.g., by using a direct oxide/nitride bonding process, as depicted in FIG. 3B. It is understood that a suitable bonding process may comprise activating and annealing steps, such as in-situ plasma pre-treatment, low-temperature annealing, and the like, to provide sufficient bond strength to ensure that surfaces are reliably connected.

As depicted in FIG. 3D, both temporary carrier 202 and dielectric layer 302 are removed, thereby exposing bottom hybrid bond pads of KGDs 206 before top KGDs 212 are hybrid-bonded to the bottom bond pads, as depicted in FIG. 3E.

FIG. 3F through FIG. 3I depict manufacturing steps similar to those discussed with reference to FIG. 2C to FIG. 2I. For brevity, these steps are summarized as follows: the wafer structure is reconstituted with encapsulating material, planarized to create a flat top surface. Then, UBM layers, onto which solder bumps can be formed, may be deposited. It is noted that, unlike in process 200, the material layer in contact with temporary carrier 202 in process 300, which provides an alignment, is removed during the process 300.

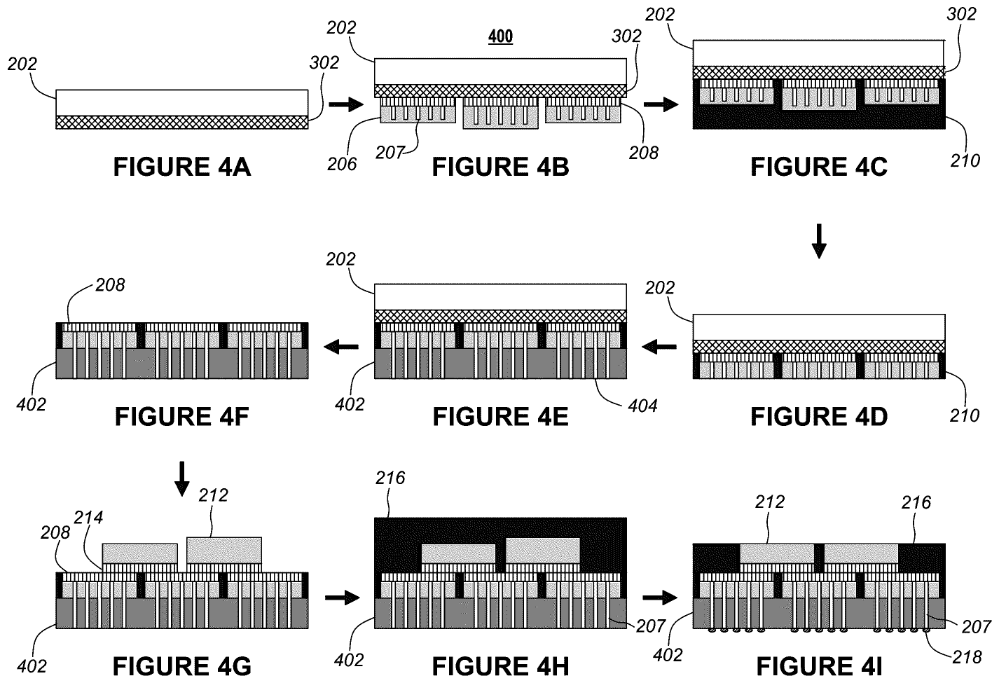

FIG. 4A through FIG. 41 illustrate yet another process for 3-D stacking dies in a staggered pattern according to various embodiments of the present disclosure. FIG. 4A to FIG. 4C are substantially similar to the manufacturing steps discussed with reference to FIG. 3A to FIG. 3C. Same numerals denote similar elements. As shown in process 400, prior to performing a CMP step that removes temporary carrier 202 to expose the bottom hybrid bond pads, depicted in FIG. 4F, bottom KGDs 206 may be thinned and flattened after backgrinding encapsulating material 210 by a planarization process, as depicted in FIG. 4D, to expose the TSVs of the bottom KGDs 206. This prepares the structure for hybrid bonding to TSVs 404 of supporting structure 402, which may be implemented as a relatively thick interposer substrate (e.g., 300 μm or more) made of silicon, organic materials, ceramic, or glass, as depicted in FIG. 4E. This step replaces encapsulating material 210 with a physical structure that exhibits superior mechanical strength properties.

Advantageously, this substitution prevents potential deformations caused by warping of molding material 210 and enhances the overall stability of the assembly. In some embodiments, supporting structure 402 may serve the functions of a wafer substrate. It is understood that TSVs 404 in interposer substrate 402 may manufactured from solid metal 802 in FIG. 8A, e.g., electroplated copper, or be metal-coated (e.g., using a metal coating 804 in FIG. 8B, such as copper that lines the walls of each via) or hollow (unfilled or filled with a filling material, such as an insulating or supportive material 806, e.g., polymer). Material 806 may alternatively be a metal or other conductive material.

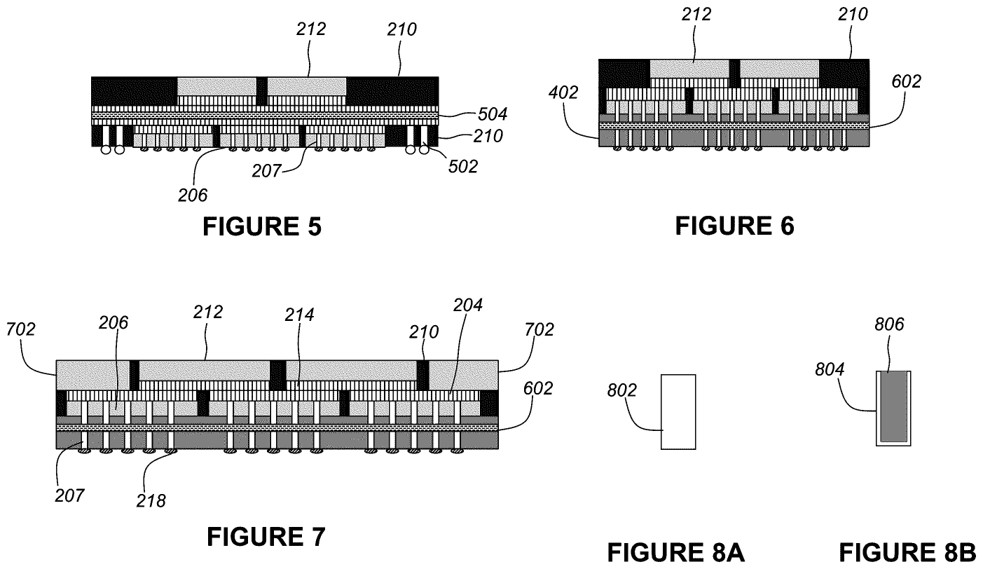

FIG. 4G through FIG. 4I of process 400 correspond to FIG. 3E to FIG. 3G for process 300. For brevity, the detailed steps are summarized as follows: the wafer structure is finalized with hybrid bonding of top KGDs 212 to the exposed bond pads, encapsulated with encapsulating material 210, and planarized to create a flat surface. The final structure, depicted in FIG. 4I, is a 3-D stack of staggered dies on top of supporting structure 402 with TSVs, providing a robust and high-performance semiconductor assembly. It is understood that, in embodiments, supporting structure 402 may also be added to structures shown in FIG. 3I, FIG. 4I, and FIG. 5.

As depicted in FIG. 5, in embodiments, thru-encapsulation-vias (TEVs) 502, which pass through encapsulating material 210, provide pathways for electrical connections, such as power and ground. Utilizing TEVs 502 in this manner offers significant advantages by freeing up TSVs 207 in bottom KGDs 206 and allowing them to be dedicated exclusively to signal transmission. Additionally, this approach helps avoid placing TSVs 207 in sensitive high-speed Serializer/Deserializer circuits, thereby enhancing overall performance and reliability. In some embodiments, routing layer 504 may be placed within intermediate array 204 to provide horizontal interconnects, for example, connecting TEV 502 to bottom KGDs 206 or top KGDs 212.

As depicted in FIG. 6, in embodiments, re-routing layers 602 may be placed on either side or both sides of supporting structure 402 (here, a relatively thick interposer substrate) to convert a bonding pad array into a TSV array, e.g., to address limitations that might arise from design or process constraints.

As depicted in FIG. 7, in some embodiments, any number of dummy dies 702 (i.e., dies that need not comprise any active circuitry) may be incorporated into one or more layers above supporting structure 402. Advantageously, dummy dies 702 enhance mechanical integrity by mechanically strengthening the stacked structure, providing additional support and stability, especially in multi-layer designs. Further, dummy dies 702 help in distributing mechanical stress evenly across an assembly, thereby reducing the risk of warping or deformation. Moreover, acting as thermal conductors, dummy dies 702 effectively dissipate heat from nearby active dies and maintain consistent temperatures within the stacked structure, thereby improving thermal management.

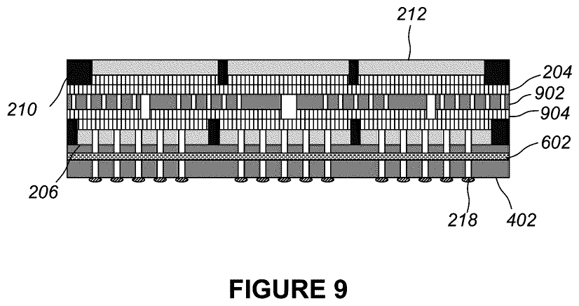

FIG. 9 illustrates an exemplary three-layer stack according to various embodiments of the present disclosure. It is understood that any number of layers comprising KGDs may be sequentially bonded using the hybrid bonding techniques presented herein. In this manner, a multi-layer 3-D stack of staggered KGDs may be constructed while ensuring consistent alignment and reliable interconnections across all layers. Advantageously, such staggered arrangements of dies enhance the electrical performance of a stack and allow for scalable manufacturing, which enables the manufacture of complex 3-D stacks having high integration density. As further shown in FIG. 9, the 3-D stack may include a supporting layer 902, which may be similar to layer 402 in one example. Supporting layer 902 may include conductor extending therethrough to provide interconnectivity between layers of the 3-D stack. Additional conductors 904 may be included to provide further interconnectivity between layers of the 3-D stack. Conductors 904 may be similar to conductors included in array 204 or hybrid bonding pads 214, for example.

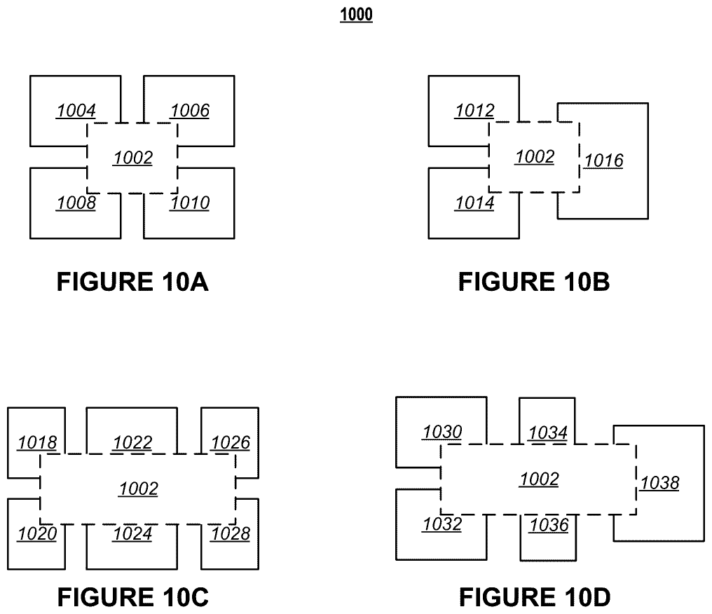

FIG. 10A through FIG. 10D are top views of exemplary multi-die interconnection arrangements between adjacent layers in a 3-D stack according to various embodiments of the present disclosure. Die 1002 in FIG. 10A through FIG. 10D represents a die in one layer and dies 1004-1038 represent dies in a layer adjacent to die 1002. In embodiments, die 1002 and dies 1004-1010 interconnect using one or more hybrid bonding systems and methods mentioned herein, as shown in FIG. 10A. Similarly, as shown in FIG. 10B, die 1002 and dies 1012-1016 interconnect, and so on.

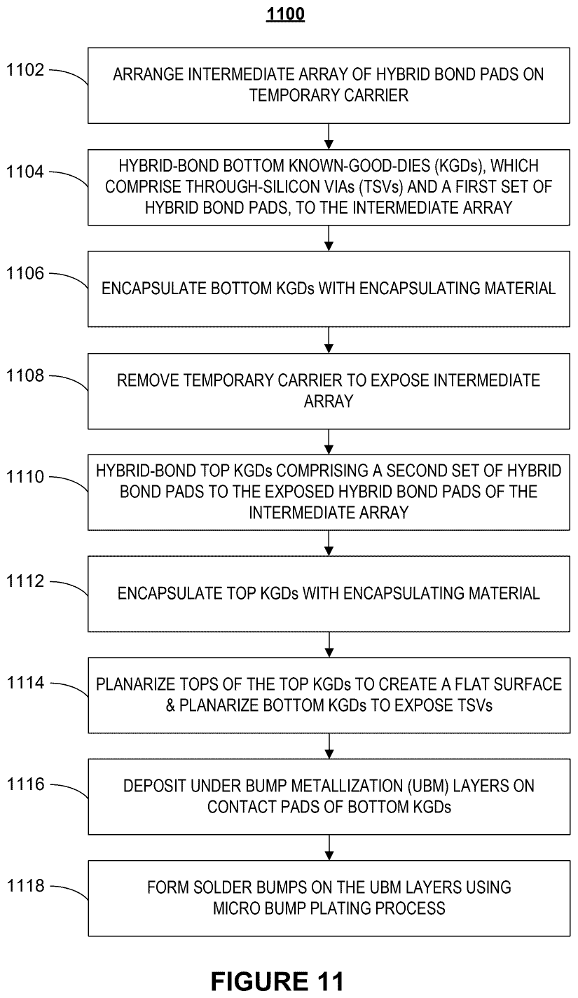

FIG. 11 is a flowchart illustrating a process for 3-D stacking dies in a staggered pattern according to various embodiments of the present disclosure. Process 1100 may begin, when at step 1102, an intermediate array of hybrid bond pads is arranged on a temporary carrier. The temporary carrier may comprise at least one of glass or silicon.

At step 1104, a set of bottom KGDs, which comprises TSVs and a first set of hybrid bond pads, is hybrid-bonded to the intermediate array.

At step 1106, the bottom KGDs are encapsulated with encapsulating material, such as an epoxy-based molding material, silicon oxide, or any combination thereof.

At step 1108, the temporary carrier is removed, e.g., using a planarization process to expose the intermediate array.

At step 1110, the top KGDs, which comprise a second set of hybrid bond pads, are hybrid-bonded to the exposed hybrid bond pads of the intermediate array.

At step 1112, the top KGDs are encapsulated with encapsulating material.

At step 1114, the tops of the top KGDs are planarized to create a flat surface and the bottom KGDs are planarized to expose their TSVs.

At step 1116, one or more UBM layers are deposited on contact pads of the bottom KGDs.

At step 1118, solder bumps are formed on the UBM layers, e.g., by using a micro bump plating process.

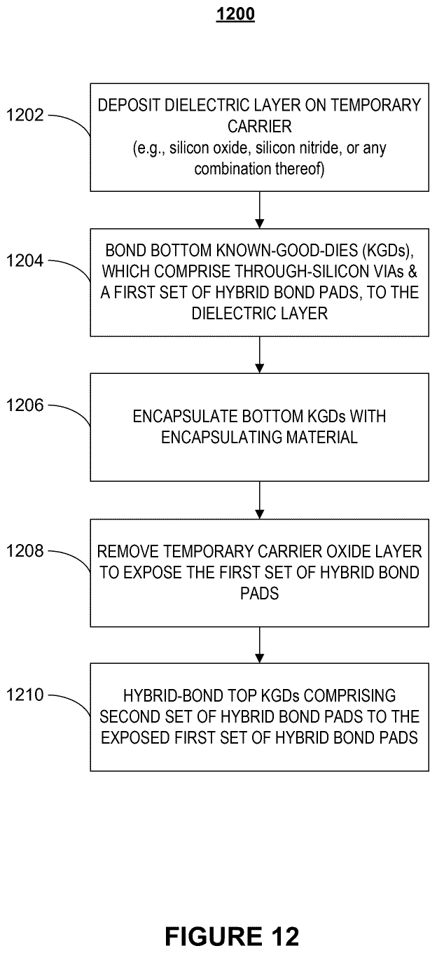

FIG. 12 is a flowchart illustrating a process for 3-D stacking dies in a staggered pattern according to various embodiments of the present disclosure. Process 1200 may begin, when at step 1202, a dielectric layer, such as silicon oxide or silicon nitride, or any combination thereof, is deposited on a temporary carrier that comprises at least one of glass or silicon.

At step 1204, a set of bottom KGDs, which comprises TSVs and a first set of hybrid bond pads, is bonded to the dielectric layer.

At step 1206, the bottom KGDs are encapsulated with encapsulating material, such as an epoxy-based molding material, silicon oxide, or any combination thereof.

At step 1208, the temporary carrier is removed, e.g., using a planarization process to expose the first set of hybrid bond pads.

At step 1210, the top KGDs, which comprise a second set of hybrid bond pads, are hybrid-bonded to the exposed first set of hybrid bond pads.

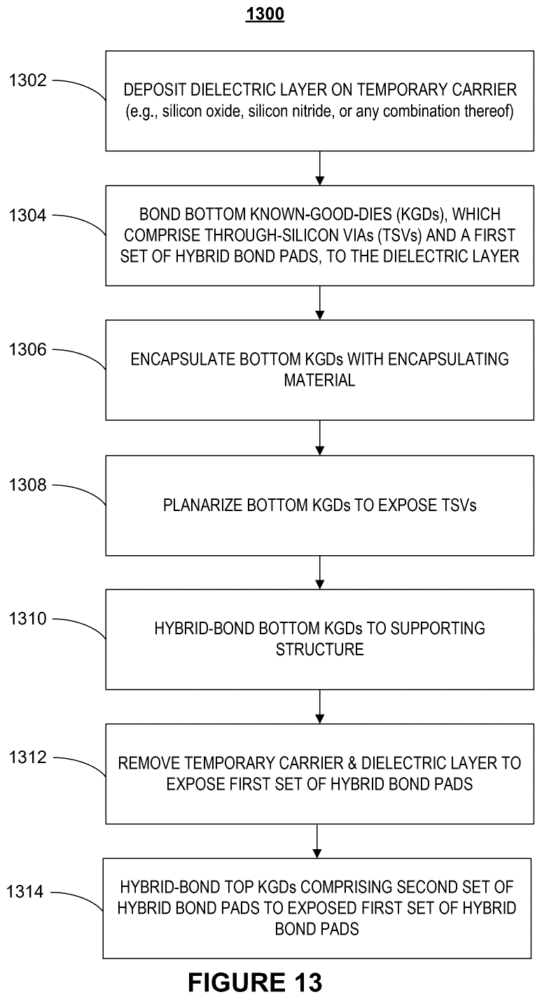

FIG. 13 is a flowchart illustrating a process for 3-D stacking dies in a staggered pattern according to various embodiments of the present disclosure. Process 1300 may begin, when at step 1302, a dielectric layer, such as silicon oxide or silicon nitride, or any combination thereof, is deposited on a temporary carrier that comprises material comprising at least one of glass, silicon, or polymer.

At step 1304, a set of bottom KGDs, which comprises TSVs and a first set of hybrid bond pads, is bonded to the dielectric layer.

At step 1306, the bottom KGDs are encapsulated with encapsulating material, such as an epoxy-based molding material, silicon oxide, or any combination thereof.

At step 1308, the bottom KGDs are planarized to expose the TSVs.

At step 1310, the bottom KGDs are hybrid-bonded to a supporting structure such as a thick interposer substrate made of silicon, organic materials, ceramic, or glass and comprising TSVs.

At step 1312, the temporary carrier and the dielectric layer are removed to expose the first set of hybrid bond pads.

At step 1314, the top KGDs comprising a second set of hybrid bond pads are hybrid-bonded to the exposed first set of hybrid bond pads.

One skilled in the art shall recognize that: (1) certain steps may optionally be performed; (2) steps may not be limited to the specific order set forth herein; (3) certain steps may be performed in different orders; and (4) certain steps may be done concurrently.

One skilled in the art will recognize no computing system or programming language is critical to the practice of the present disclosure. One skilled in the art will also recognize that a number of the elements described above may be physically and/or functionally separated into modules and/or sub-modules or combined.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

1. A method, comprising:
providing a dielectric layer on a carrier, the dielectric layer having a first side that faces away from the carrier and a second side that faces the carrier;
bonding first bonding pads to the dielectric layer, the first bonding pads being formed on first semiconductor die, the first semiconductor die including conductors;
providing a layer of a first material on the carrier that encapsulates the first semiconductor die;
removing the carrier and the dielectric layer;
bonding second bonding pads to the first bonding pads, the second bonding pads being formed on second semiconductor die;
providing a layer of a second material that encapsulates the second semiconductor die;
thinning the second material to expose portions of the second semiconductor die; and
thinning the first material to expose the second conductors included in the first semiconductor die.

2. The method of claim 1, further including forming conductive bumps on the second conductors included in the first semiconductor die.

3. The method of claim 1, further including providing the second conductors as through silicon vias in the first semiconductor die.

4. The method of claim 1, wherein each of the first bonding pads and each of the second bonding pads includes copper.

5. The method of claim 1, wherein the carrier include one of the following: glass, silicon, and a polymer.

6. A method in accordance with claim 1, wherein the first material includes a silicon oxide.

7. A method in accordance with claim 1, wherein the second material includes a silicon oxide.

8. A method in accordance with claim 1, wherein the carrier includes at least one alignment mark for placing the first semiconductor die on the carrier.

9. A method in accordance with claim 1, wherein the step of removing the carrier includes one of: carrier debond, backgrinding, and etching.

10. A method in accordance with claim 1, further including a planarization process following the step of removing the carrier.

11. A method in accordance with claim 10, wherein the planarization process includes one of chemical mechanical polishing (CMP) and electrochemical planarization (ECP).

12. A method in accordance with claim 1, wherein the step of providing a layer of a second material that encapsulates the second semiconductor die includes one of: a gap-fill process, an overmolding process, or covering the second semiconductor die with an oxide.

13. A method in accordance with claim 1, wherein the step of thinning the second material includes one of chemical mechanical polishing (CMP) and electrochemical planarization (ECP).

14. A method in accordance with claim 1, wherein the step of thinning the first material includes one of chemical mechanical polishing (CMP) and electrochemical planarization (ECP).

15. A method, comprising:
providing an array of first conductors on a carrier, the array of first conductors having a first side that faces away from the carrier and a second side that faces the carrier;
hybrid bonding first bonding pads to the array of conductors, the first bonding pads being formed on first semiconductor die, the first semiconductor die including second conductors;
providing a layer of a first material on the carrier that encapsulates the first semiconductor die;
removing the carrier;
hybrid bonding second bonding pads to the second side of the array of first conductors, the second bonding pads being formed on second semiconductor die;
providing a layer of a second material that encapsulates the second semiconductor die;
thinning the second material to expose portions of the second semiconductor die; and
thinning the first material to expose the second conductors included in the first semiconductor die.

16. The method of claim 15, further including forming conductive bumps on the second conductors included in the first semiconductor die.

17. The method of claim 15, further including providing the second conductors as through silicon vias in the first semiconductor die.

18. The method of claim of claim 15, wherein each of the first bonding pads and each of the second bonding pads includes copper.

19-28. (canceled)

29. A method, comprising:
providing a dielectric layer on a carrier, the dielectric layer having a first side that faces away from the carrier and a second side that faces the carrier;
bonding first bonding pads to the dielectric layer, the first bonding pads being formed on first semiconductor die, the first semiconductor die including first conductors;
providing a layer of a first material on the carrier that encapsulates the first semiconductor die;
thinning the first material and the first semiconductor die, thereby exposing portions of the conductors;
hybrid bonding a supporting structure including second conductors to the first semiconductor die, such that the first conductors are aligned with the second conductors;
removing the dielectric layer and the carrier to thereby expose the first bonding pads;
bonding second bonding pads to the first bonding pads, the second bonding pads be provided on second semiconductor die;
providing a layer of a second material that encapsulates the second semiconductor die; and
thinning the second material to expose portions of the second semiconductor die.

30. The method of claim 29, further including forming conductive bumps on the second conductors included in the supporting structure.

31-32. (canceled)
